(19) United States
(12) Patent Application Publication
(10) Pub. No.: US 2015/0028880 A1
(43) Pub. Date: Jan. 29, 2015

(54) Electronic Apparatus, Method of Controlling Electronic Apparatus, and Storage Medium

(71) Applicant: Kabushiki Kaisha Toshiba, Tokyo (JP)

(72) Inventor: Makoto Midorikawa, Hamura-shi (JP)

(21) Appl. No.: 14/330,683

(22) Filed: Jul. 14, 2014

Related U.S. Application Data
(60) Provisional application No. 61/859,045, filed on Jul. 26, 2013.

(51) Int. Cl. G01R 31/36

(52) U.S. Cl. CPC G01R 31/3606
USPC 324/435; 324/426

(57) ABSTRACT

An electronic apparatus of an embodiment includes a comparison section which, in the case where a long-life mode of a battery is set, compares a battery detection value with a second low-battery detection value that is higher than a first low-battery detection value. The apparatus further includes a change detection section which detects a change of a power supply. The apparatus further includes a change reflect section which, in the case where it is detected both that the battery detection value is lower than the second low-battery detection value, and that the power supply is changed, changes the low-battery detection value to the second low-battery detection value.

### CROSS-REFERENCE TO RELATED APPLICATION(S)

This application claims priority from U.S. Provisional Patent Application No. 61/859,045 filed on Jul. 26, 2013, the entire contents of which are incorporated herein by reference.

### FIELD

An embodiment of the present invention relates to an electronic apparatus, a method of controlling an electronic apparatus, and a storage medium.

### BACKGROUND ART

Recently, portable electronic apparatuses (mobile apparatuses) which can be driven also by, for example, a battery power supply are in widespread use. As batteries for such electronic apparatuses, for example, secondary cells are used. Secondary cells are also called electric accumulators or rechargeable cells. A battery (secondary cell) is a cell (chemical cell) which, when charged, stores electricity, and which can be repeatedly used.

In general, when charging/discharging (charge and discharge) of a battery (secondary cell) is repeated, usually, the chargeable capacity of the battery is gradually reduced or deteriorated (cycle characteristic). Thus, it has been requested to prolong the life of a battery (secondary cell) used in an electronic apparatus.

### BRIEF DESCRIPTION OF THE DRAWINGS

FIG. 1 is a block diagram showing an exemplary system configuration of an electronic apparatus of an embodiment.

FIG. 2 is a predictive conceptual diagram illustrating an effect on the cycle characteristic in the case where the discharge cease voltage is changed in the electronic apparatus of the embodiment.

FIG. 3 is a view showing an exemplary battery long-life setting screen which is displayed and output on a display section of the electronic apparatus of the embodiment.

FIG. 4 is a flowchart illustrating an exemplary process of changing “Low-battery detection level” in the electronic apparatus of the embodiment.

FIGS. 5A and 5B are flowcharts illustrating exemplary processes of changing “Low-battery detection level” in the electronic apparatus of the embodiment.

FIG. 6 is a flowchart illustrating a process of changing “Low-battery detection level” in the case where battery deterioration is detected in the electronic apparatus of the embodiment.

FIG. 7 is a flowchart illustrating an operation related to a long-life mode in the electronic apparatus of the embodiment.

FIG. 8 is a flowchart illustrating an operation related to battery deterioration detection in the electronic apparatus of the embodiment.

### DETAILED DESCRIPTION

Hereinafter, an embodiment will be described with reference to the drawings.

Usually, a battery (battery pack) 15 has a function of, when reaching the discharge cease voltage (cut-off voltage), for example, turning off a FET switch to cease discharge, thereby stopping power supply to the outside of the battery.

Recently, it has been known that, when the discharge cease voltage (cut-off voltage) of a battery is raised (heightened), the deterioration of the capacity due to the cycle characteristic of the battery 15 can be suppressed by raising the cut-off voltage as compared to the case where the cut-off voltage is not raised. That is, it has been known that, in discharging of a battery, the discharge is not performed up to the limit, but ceased in a state having a certain degree of margin, whereby the deterioration rate of the capacity due to the cycle characteristic can be relieved.

In a scene of using a usual electronic apparatus (mobile apparatus), it is rare that the user consumes a battery up to the discharge cease voltage (cut-off voltage). This is because, for example, an exhaustion detection level (value) (low-battery detection level (value)) is set in the electronic apparatus (mobile apparatus). This is furthermore because the low-battery detection level (value) is set to a value which is higher than the discharge cease voltage (cut-off voltage) level (value) of the battery. A low level (value) (low-battery detection level (value)) may be set as a threshold for detecting reduction in the battery (battery pack) 15 of the electronic apparatus (PC) 10, i.e., battery exhaustion.

In an electronic apparatus (mobile apparatus), for example, an operation in the case where battery exhaustion is detected (low-battery detection) is previously set by built-in software (microcomputer FW, or software on the OS). According to such configuration, in the case where a low battery is detected, the electronic apparatus (mobile apparatus) is set to a quiescent state (or a power-off state).

When the electronic apparatus (mobile apparatus) is set to a quiescent state (or a power-off state), the power consumption of the electronic apparatus (mobile apparatus) is largely reduced. Therefore, discharge from the battery becomes small as if the battery is in a state of the discharge stop.

In the embodiment, in a battery long-life setting, namely, “Low-battery detection level (value)” is changed (raised) to a second low-battery detection value which is higher than the initial set value (first low-battery detection value). Thus, the reduction rate of the battery capacity due to the cycle characteristic can be relieved, and the life of a battery (secondary cell) can be prolonged.

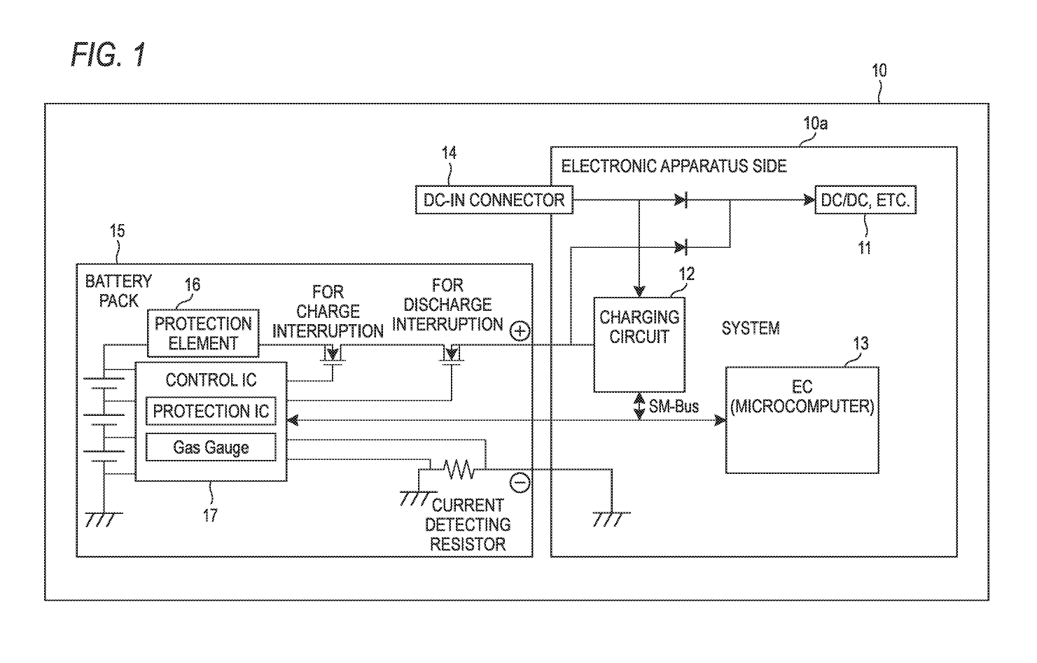

FIG. 1 is a block diagram showing an exemplary system configuration of the electronic apparatus of the embodiment.

Although a personal computer (PC) is exemplified as the electronic apparatus, the electronic apparatus is not limited to a PC. The invention of the embodiment can be applied also to, for example, a tablet PC, a smart phone, a television receiver, and the like.

In the electronic apparatus (PC) 10, as shown in FIG. 1, the battery (battery pack) 15 is connected to the electronic apparatus side 10a. The battery (battery pack) 15 may be wholly housed in the electronic apparatus (PC) 10. The electronic apparatus side 10a of the electronic apparatus (PC) 10 includes a DC/DC converter 11, a charging circuit 12, an EC (microcomputer) 13, a DC power supply input connector 14, and the like. The battery (battery pack) 15 includes a protection element 16, a control IC 17, and the like.

The electronic apparatus (PC) 10 of the embodiment further includes a comparison section (the EC (microcomputer) 13 and the like) which, in the case where the long-life mode of the battery (battery pack) 15 is set, compares “Low-battery detection value” with the second low-battery detection value (for example, 9.6 V in total of 3 cells) that is larger than the first low-battery detection value (for example, 9.0 V in total of 3 cells).

The electronic apparatus further includes a change detection section (the EC (microcomputer) 13 and the like) which detects a change of the power supply.

The electronic apparatus further includes a change reflect section (the EC (microcomputer) 13 and the like) which, in the case where it is detected both that the battery detection value is lower than the second low-battery detection value (9.6 V), and that the power supply is changed (a switch to AC drive, a connection of the battery, or the like), changes the low-battery detection value to the second low-battery detection value (9.6 V).

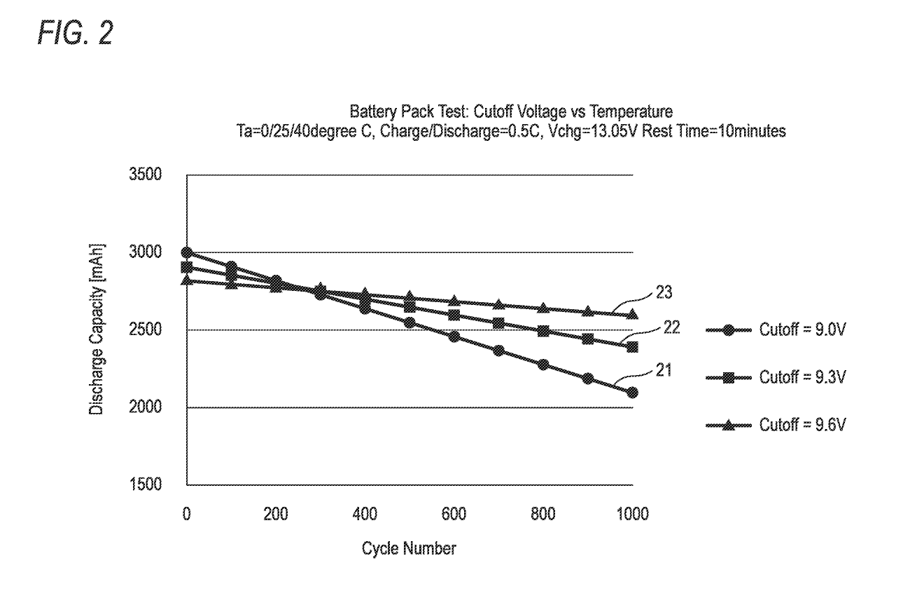

FIG. 2 is a predictive conceptual diagram illustrating an effect on the cycle characteristic in the case where the discharge cease voltage (cut-off voltage) is changed in the electronic apparatus of the embodiment. In this embodiment, the battery pack includes three cells.

In FIG. 2, the cycle numbers in the case where the discharge cease voltage (cut-off voltage) is set to each of 9.0 V (21), 9.3 V (22), and 9.6 V (23) are compared with one another. Based on the comparison between the case where the cut-off voltage is 9.0 V (21) and the case where the cut-off voltage is 9.3 V (22), for example, the reduction of the cycle number in the case of the higher cut-off voltage, i.e., 9.3 V (22) is gentler than that in the case of 9.0 V (21). In other words, the life of the battery (secondary cell) in the case of the higher cut-off voltage, i.e., 9.3 V (22) is longer (has a longer life) than that in the case of 9.0 V (21).

Similarly, when the case where the cut-off voltage is 9.3 V (22) is compared with the case where the cut-off voltage is 9.6 V (23), the reduction of the cycle number in the case of the higher cut-off voltage, i.e., 9.6 V (23) is gentler than that in the case of 9.3 V (22). In other words, the life of the battery (secondary cell) in the case of the higher cut-off voltage, i.e., 9.6 V (23) is longer (has a longer life) than that in the case of 9.3 V (22).

In the embodiment, as to the battery detection value which is set in the EC (microcomputer) 13 of the electronic apparatus (PC) 10, for example, the first low-battery detection value is set to 9.0 V, and the second low-battery detection value which is higher than the first low-battery detection value is set to 9.6 V. These values can be adequately changed as required.

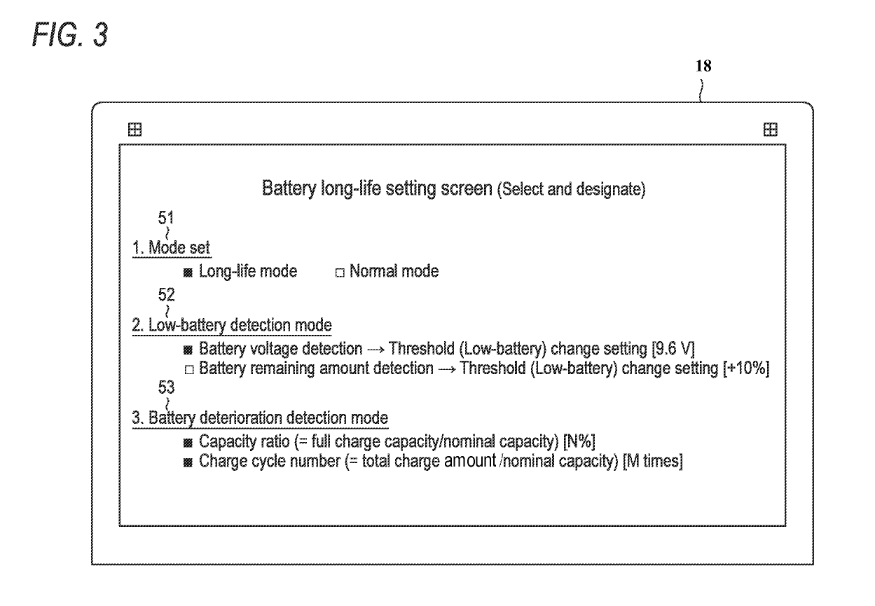

FIG. 3 is a view showing an exemplary battery long-life setting screen which is displayed and output on a display section of the electronic apparatus of the embodiment.

In the embodiment, as shown in FIG. 3, “Battery long-life setting screen” is displayed and output on a display section 18 of the electronic apparatus (PC) 10. Specifically, “Battery long-life setting screen (Select and designate)” is output on the display section 18.

As “1. Mode set”, “▪ Long-life mode” and “□ Normal mode” are displayed and output in a selectable and designatable manner (51). Annexation of “▪” to “Long-life mode” indicates that it is designated.

As “2. Low-battery detection mode”, “▪ Battery voltage detection→Threshold (Low-battery) change setting [9.6 V]” and “□ Battery remaining amount detection→Threshold (Low-battery) change setting [+10%]” are displayed and output in a selectable and designatable manner (52). It is indicated that “▪ Battery voltage detection→Threshold (Low-battery) change setting [9.6 V]” is designated. To facilitate the control, it is preferable to designate either one of “Battery voltage detection” and “Battery remaining amount detection”. For example, a value of [9.6 V] may be selected from a predetermined value or directly input by the user.

As “3. Battery deterioration detection mode”, “▪ Capacity ratio (=full charge capacity/nominal capacity) [N %]” and “▪ Charge cycle number (=total charge amount/nominal capacity) [M times]” are displayed and output in a selectable and designatable manner (53). N and M are arbitrary numerals. It is indicated that both “Capacity ratio (=full charge capacity/nominal capacity)” and “Charge cycle number (=total charge amount/nominal capacity)” are designated. Both or either one of “Capacity ratio (=full charge capacity/nominal capacity)” and “Charge cycle number (=total charge amount/nominal capacity)” may be designated. Values of [N %] and [M times] may be selected from a predetermined value or directly input by the user.

The electronic apparatus (PC) 10 of the embodiment has a function of changing “Low-battery detection level” upon the user's selection/designation of the long-life mode to thereby enable the battery life to be prolonged.

In the case where the user activates the function (selects the long-life mode), for example, an application on the OS (or a utility application) notifies the microcomputer 13 of the electronic apparatus (PC) 10 of a request for changing “Low-battery detection level”. Then, a process of changing “Low-battery detection level” is executed in the microcomputer 13.

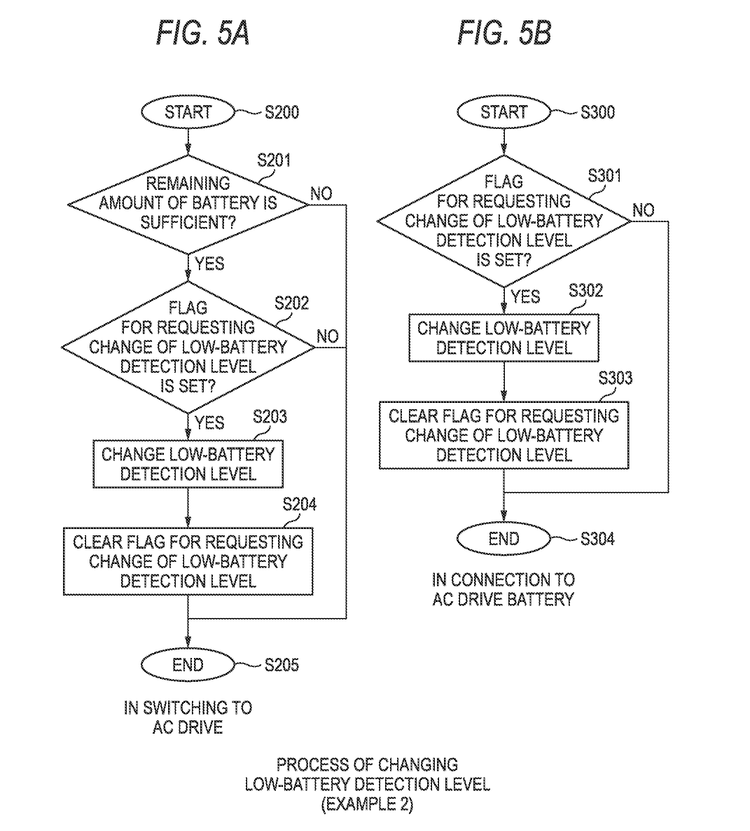

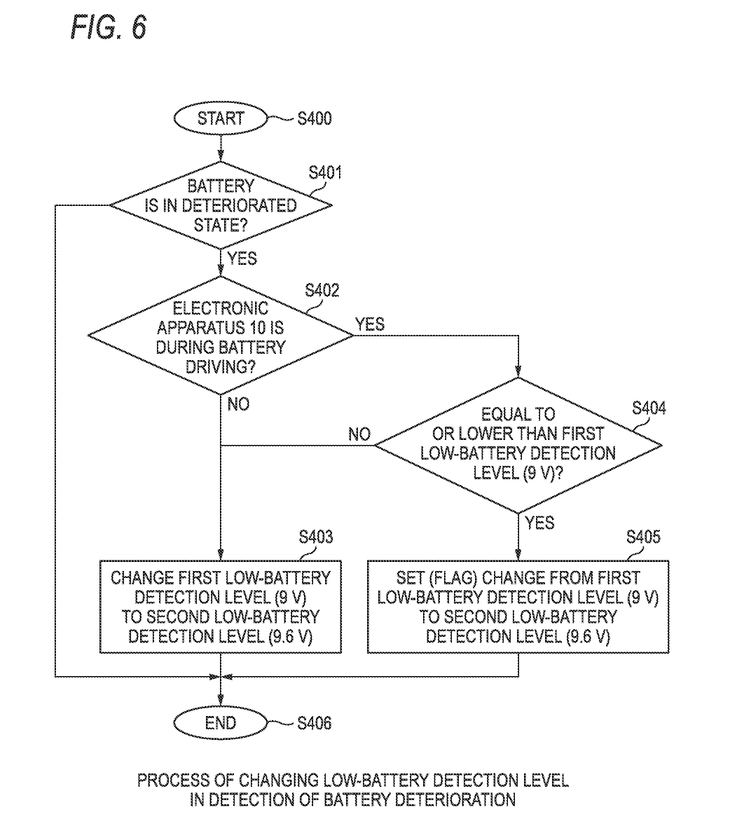

FIGS. 5A to 6 show the process of changing “Low-battery detection level” in the microcomputer 13.

In the embodiment, in the case where this function is activated during when the electronic apparatus (PC) 10 is driven by the battery 15 and the battery 15 is equal to or lower than the changed low-battery detection level (second low-battery detection level), the low-battery detection level is not immediately changed.

In this case, for example, the request (flag) for changing “Low-battery detection level” is set, but the set value (first low-battery detection level) of “Low-battery detection level” is made unchanged. As described later, then, the change request (flag) is checked at a timing when the power supply to the electronic apparatus (PC) 10 is switched to AC drive, or that when the battery 15 is connected, and the process of changing “Low-battery detection level” is executed.

Hereinafter, “System for low-battery detection” in the embodiment will be described. As “Method of low-battery detection”, for example, there are the following two methods.

(1) Method of Detecting Low-Battery from Battery Voltage Value

When the battery 15 becomes discharged, the voltage of the battery is gradually lowered. And, in the system, in the case where the battery voltage of the battery 15 is lowered to be equal to or below a certain threshold, the low battery is detected. For example, the battery voltage is monitored by the control IC 17 of the battery pack 15. Then, the microcomputer 13 disposed in the electronic apparatus side 10a communicates with the control IC 17 in, for example, a periodical manner to acquire the voltage value of the battery 15.

Alternatively, the microcomputer 13 disposed in the electronic apparatus side 10a directly measures/monitors the battery voltage of the battery 15.

(2) Method of Detecting from Remaining Amount of Battery

For example, the remaining amount of the battery (battery pack) 15 is calculated by a gauge (Gas Guage) disposed in the control IC 17. And, in the system, when the remaining amount of the battery 15 becomes equal to or smaller than a certain value (%) of the full charge capacity, the low-battery is detected. The microcomputer 13 of the electronic apparatus side 10a communicates with, for example, the control IC 17 in a periodical manner, and can acquire the remaining amount of the battery 15.

Hereinafter, “Method of changing low-battery detection level” in the embodiment will be described.

(1) Method of Changing “Low-Battery Detection Voltage” as “Low-Battery Detection Level”

“Low-battery detection voltage” as “Low-battery detection level” is raised (heightened) higher than a preset value (first low-battery detection level) to thereby prolong the life of the battery 15. “Low-battery detection voltage” is managed by the microcomputer 13 of the electronic apparatus side 10a. And, “Low-battery detection level (voltage set value)” which is set in the microcomputer 13 is changed to a set value (second low-battery detection level) corresponding to the long-life mode.

(2) as “Low-Battery Detection Level”, the Value of “Low-Battery Detection Battery Remaining Amount” (Remaining Amount/Full Charge Capacity) [%] is Changed.

“Low-battery detection battery remaining amount” is raised (heightened) higher than the initial set value (preset value (first low-battery detection level)) to thereby further prolong the life of the battery 15.

In the case where the user can set and change “Low-battery detection level” through software on the OS, even if the function is effective, it is preferable to disable change of the setting as to “Low-battery detection level” by the user. In the case where the user can set and change the operation in response to “Low-battery detection” through software on the OS or the like, such operation may be automatically set and changed to a quiescent state (a state where the power consumption is further reduced, such as Sleep). Also in this case, even if the setting as to the operation in response to the detection is changeable, it is preferable to disable change of the setting by the user. According to the configuration, the convenience of the user can be improved.

In the embodiment, moreover, a process of detecting deterioration of the battery 15 and prolonging the life may also be performed.

For example, the deterioration degree of the battery 15 is determined by using battery information. A function may be configured such that, if it is determined that deterioration proceeds to some extent, for example, “Low-battery detection level” is changed to prolong the life of the battery 15. For example, after the deterioration determination, the user may select whether or not to change the low-battery detection level.

FIG. 6 shows an exemplary process of changing the low-battery detection level in accordance with the determination of battery deterioration.

When “Low-battery detection level is raised (heightened), for example, the battery driving time per charge is shortened. In view of above, a user may prefer a manner of use in which the low-battery detection level is changed to prolong the life of the battery upon deterioration of a battery to some extent. Therefore, a function of performing such battery deterioration determination may also be convenience.

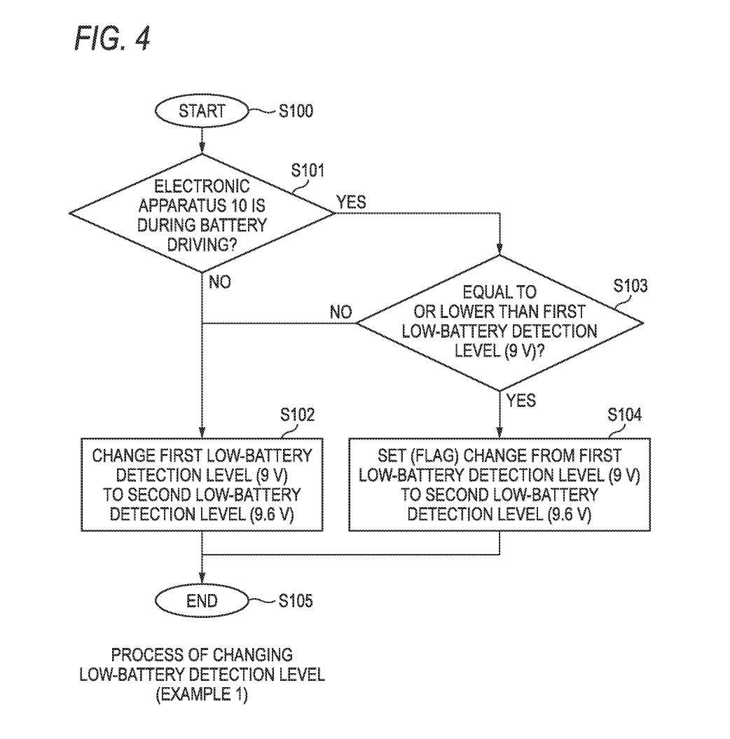

FIG. 4 is a flowchart illustrating an exemplary process of changing “Low-battery detection level” in the electronic apparatus of the embodiment.

Step S100 is the start step of the process. Then, the process proceeds to step S101. Step S101 is a step of detecting whether the electronic apparatus 10 is during battery driving or not. If it is detected that the electronic apparatus 10 is during battery driving, the process proceeds to step S103 (Yes). If it is detected that the electronic apparatus 10 is not during battery driving, the process proceeds to step S102 (No).

Step S102 is a step of changing the preset first low-battery detection level (9 V) to the second low-battery detection level (9.6 V). Then, the process proceeds to step S105.

Step S103 is a step of detecting whether the voltage value of the battery 15 is equal to or lower than the first low-battery detection level (9 V) or not. If it is detected that the voltage value of the battery 15 is equal to or lower than the first low-battery detection level (9 V), the process proceeds to step S104 (Yes). If it is detected that the voltage value of the battery 15 is not equal to or lower than the first low-battery detection level (9 V), the process proceeds to step S102 (No).

Step S104 is a step of setting “Low-battery detection level” to the EC (microcomputer) 13 of the electronic apparatus (PC) 10 so that the level is changed from the first low-battery detection level (9 V) to the second low-battery detection level (9.6 V). For example, the setting to the EC (microcomputer) 13 is realized by setting a flag. Then, the process proceeds to step S105.

Step S105 is the end step, and the process ends.

FIGS. 5A and 5B are flowcharts illustrating exemplary processes of changing “Low-battery detection level” in the electronic apparatus of the embodiment.

FIG. 5A illustrates the operation in the case where the electronic apparatus (PC) 10 is switched to AC drive. Step S200 is the start step of the process. Then, the process proceeds to step S201. Step S201 is a step of detecting whether the remaining amount of the battery 15 is sufficient or not. If it is detected that the remaining amount of the battery 15 is sufficient, the process proceeds to step S202 (Yes). If it is detected that the remaining amount of the battery 15 is not sufficient, the process proceeds to step S205 (No).

Step S202 is a step of detecting whether a request for changing “Low-battery detection level”, such as a change request flag is set or not. If the request for changing “Low-battery detection level” is set, the process proceeds to step S203 (Yes). If the request for changing “Low-battery detection level” is not set, the process proceeds to step S205 (No).

Step S203 is a step of changing “Low-battery detection level”. Then, the process proceeds to step S204. Step S204 is a step of clearing the request (flag) for changing “Low-battery detection level”. Then, the process proceeds to step S205. Step S205 is the end step, and the process ends.

FIG. 5B illustrates the operation in the case where the electronic apparatus (PC) 10 is switched to an AC drive battery.

Step S300 is the start step of the process. Then, the process proceeds to step S301. Step S301 is a step of detecting whether a request (flag) for changing “Low-battery detection level” is set or not. If it is detected that the request (flag) for changing “Low-battery detection level” is set, the process proceeds to step S302 (Yes). If it is detected that the request (flag) for changing “Low-battery detection level” is not set, the process proceeds to step S304 (No).

Step S302 is a step of changing “Low-battery detection level” which is set in the electronic apparatus (PC) 10. Then, the process proceeds to step S303. Step S303 is a step of clearing the request (flag) for changing “Low-battery detection level”. Then, the process proceeds to step S304. Step S304 is the end step, and the process is ended.

FIG. 6 is a flowchart illustrating a process of changing “Low-battery detection level” in the case where battery deterioration is detected in the electronic apparatus of the embodiment.

Step S400 is the start step of the process. Then, the process proceeds to step S401. Step S401 is a step of detecting whether the battery 15 is in a deteriorated state or not. If it is detected that the battery 15 is in a deteriorated state, the process proceeds to step S402 (Yes). If it is detected that the battery 15 is not in a deteriorated state, the process proceeds to step S406 (No).

Hereinafter, examples of a method of determining the deterioration degree of the battery will be described.

(1) for Example, Determination (Detection) of the Deterioration Degree of the Battery May be Made Based on “Ratio of Current Full Charge Capacity and Nominal Capacity (=Full Charge Capacity/Nominal Capacity)”.

The control IC 17 learns the use status of the battery pack 15, and the value of the full charge capacity is gradually changed. The nominal capacity is a fixed value.

When “Ratio of current full charge capacity and nominal capacity (=full charge capacity/nominal capacity)” becomes equal to or smaller than a predetermined threshold, for example, it is determined that deterioration occurs. Then, a function of prolonging the battery life in the embodiment is made effective, and “Low-battery detection level” is changed (raised).

For example, the embodiment may be configured so that, as the value of the predetermined threshold, the user can select from plural candidates, or arbitrarily set within a predetermined range.

(2) for Example, Determination (Detection) of the Deterioration Degree of the Battery May be Made Based on “Cycle Number (=Total Discharge Amount/Nominal Capacity)”.

When “Cycle number” becomes equal to or larger than a predetermined threshold, it is determined that deterioration occurs. Then, “Function of prolonging battery life” is made effective, and “Low-battery detection level” is changed (raised).

The embodiment may be configured so that, as the value of the predetermined threshold, the user can select from plural candidates, or arbitrarily set within a predetermined range.

Alternatively, the embodiment may be configured so that deterioration is determined by independently using “Ratio of current full charge capacity and nominal capacity (=full charge capacity/nominal capacity)” and “Cycle number (=total discharge amount/nominal capacity or the like)”, or so that deterioration is determined while adequately combining them.

Step S402 is a step of detecting whether the electronic apparatus 10 is during battery driving or not. If it is detected that the electronic apparatus 10 is during battery driving, the process proceeds to step S404 (Yes). If it is detected that the electronic apparatus 10 is not during battery driving, the process proceeds to step S403 (No).

Step S404 is a step of detecting whether the battery detection level of the battery 15 is equal to or lower than the first low-battery detection level (9 V) or not. If it is detected that the battery detection level of the battery 15 is equal to or lower than the first low-battery detection level (9 V), the process proceeds to step S405 (Yes). If it is detected that the battery detection level of the battery 15 is not equal to or lower than the first low-battery detection level (9 V), the process proceeds to step S403 (No).

Step S405 is a step of setting (setting a flag) a change in which “Low-battery detection level” that is set in the electronic apparatus (PC) 10 is changed from the first low-battery detection level (9 V) to the second low-battery detection level (9.6 V). Then, the process proceeds to step S406.

Step S406 is the end step, and the process ends.

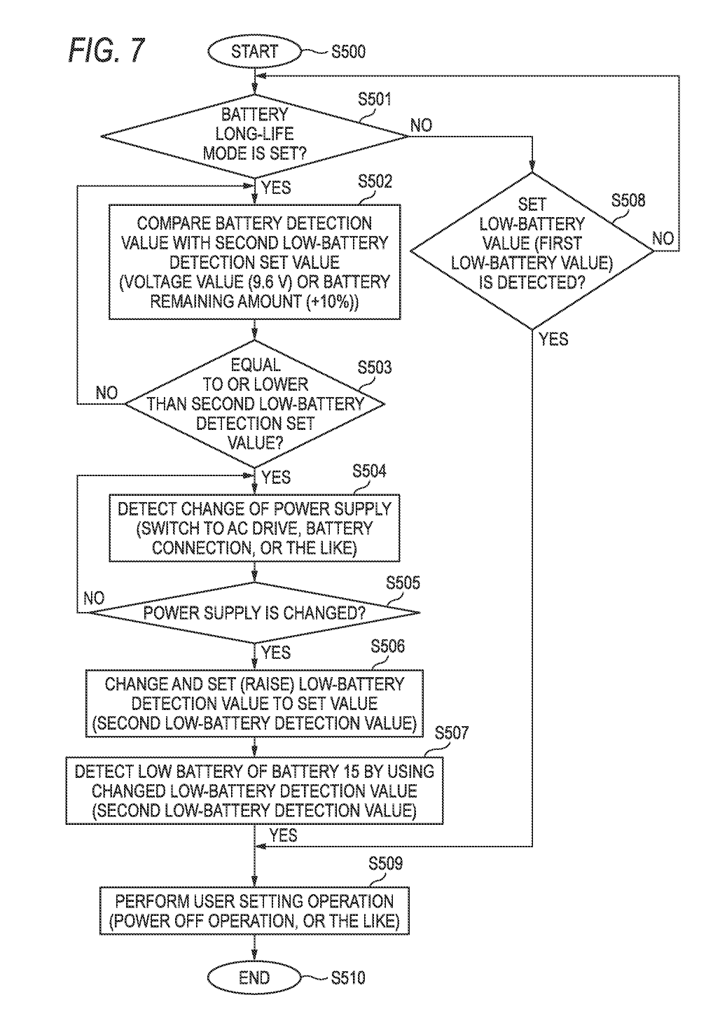

FIG. 7 is a flowchart illustrating an operation related to “Long-life mode” in the electronic apparatus of the embodiment.

Step S500 is the start step of the process. Then, the process proceeds to step S501. Step S501 is a step of detecting whether “Battery long-life mode” is set in the electronic apparatus (PC) 10 or not. If it is detected that “Battery long-life mode” is set in the electronic apparatus (PC) 10, the process proceeds to step S502 (Yes). If it is not detected that “Battery long-life mode” is set in the electronic apparatus (PC) 10, the process proceeds to step S508 (No).

Step S502 is a step of comparing the battery detection value (for example, the voltage value or the battery remaining amount) of the electronic apparatus (PC) 10 with “Second low-battery detection set value”.

For example, “Second low-battery detection set value” is “9.6 V” in the case of the voltage value, or “+10%” in the case of the battery remaining amount. Then, the process proceeds to step S503.

Step S503 is a step of detecting whether the battery detection value of the electronic apparatus (PC) 10 is equal to or smaller than the second low-battery detection set value or not. If it is detected that the battery detection value of the electronic apparatus (PC) 10 is equal to or smaller than the second low-battery detection set value, the process proceeds to step S504 (Yes). If it is detected that the battery detection value of the electronic apparatus (PC) 10 is not equal to or smaller than the second low-battery detection set value, the process proceeds to step S502 (No).

Step S504 is a step of performing detection of a change of the power supply. For example, a change of the power supply is a switch to AC drive, or that to a connection of the battery or the like. Then, the process proceeds to step S505.

Step S505 is a step of detecting whether the power supply is changed or not. If it is detected that the power supply is changed, the process proceeds to step S506 (Yes). If it is not detected that the power supply is changed, the process proceeds to step S504 (No).

Step S506 is a step of changing and setting (raising) the low-battery detection value from the initial value (first low-battery detection value) to a value (second low-battery detection value) which is set correspondingly with designation of “Long-life mode”. Then, the process proceeds to step S507.

Step S507 is a step of detecting the low battery of the battery 15 based on the changed low-battery detection value (second low-battery detection value). Then, the process proceeds to step S509.

Step S508 is a step of detecting the set low-battery value (first low-battery value). If the low-battery value (first low-battery value) is detected, the process proceeds to step S509 (Yes). If the low-battery value (first low-battery value) is not detected, the process proceeds to step S501, and the above-described process is repeated (No).

Step S509 is a step of performing a user setting operation such as a power OFF operation. Then, the process proceeds to step S510. Step S510 is the end step, and the process ends.

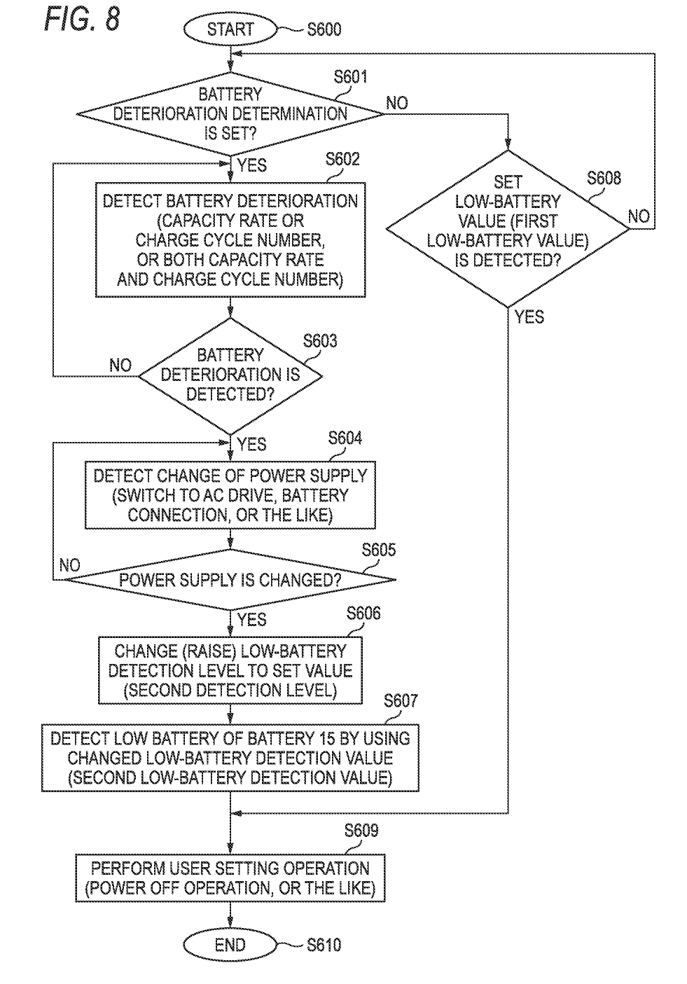

FIG. 8 is a flowchart illustrating an operation related to battery deterioration detection in the electronic apparatus of the embodiment.

Step S600 is the start step of the process. Then, the process proceeds to step S601. Step S601 is a step of detecting whether a process of “Battery deterioration determination” is set or not. If it is detected that the process of determining “Battery deterioration” is set, the process proceeds to step S602 (Yes). If it is not detected that the process of determining “Battery deterioration” is set, the process proceeds to step S608 (No).

Step S602 is a step of detecting “Battery deterioration”. For example, “Battery deterioration” is detected by using one of “Capacity rate” and “Charge cycle number”, or adequately combining both “Capacity rate” and “Charge cycle number”, of the battery 15 together. Then, the process proceeds to step S603.

Step S603 is a step of determining whether “Battery deterioration” is detected or not. If it is determined that “Battery deterioration” is detected, the process proceeds to step S604 (Yes). If it is not determined that “Battery deterioration” is detected, the process proceeds to step S602 (No).

Step S604 is a step of detecting a change of the power supply, i.e., a switch to AC drive, a connection of the battery, or the like. Then, the process proceeds to step S605.

Step S605 is a step of detecting whether the power supply is changed or not. If it is detected that the power supply is changed, the process proceeds to step S606 (Yes). If it is not detected that the power supply is changed, the process proceeds to step S604 (No).

Step S606 is a step of changing (raising) the low-battery detection level to a set value (second detection level). Then, the process proceeds to step S607. Step S607 is a step of detecting the low battery of the battery 15 based on the changed low-battery detection value (second low-battery detection value). Then, the process proceeds to step S609.

Step S608 is a step of detecting the set low-battery value (first low-battery value). If the low-battery value (first low-battery value) is detected, the process proceeds to step S609 (Yes). If the low-battery value (first low-battery value) is not detected, the process proceeds to step S601, and the above-described process is repeated (No).

Step S609 is a step of performing a user setting operation such as a power OFF operation. Then, the process proceeds to step S610. Step S610 is the end step, and the process ends.

As described above, the electronic apparatus (PC) 10 of the embodiment includes:

the comparison section (EC (microcomputer) 13 and the like) which, in the case where the long-life mode of the battery (battery pack) 15 is set, compares “Low-battery detection value” with the second low-battery detection value (for example, 9.6 V in total of 3 cells) that is higher than the first low-battery detection value (for example, 9.0 V in total of 3 cells); the change detection section (EC (microcomputer) 13 and the like) which detects a change of the power supply; and the change reflect section (EC (microcomputer) 13 and the like) which, in the case where it is detected both that the battery detection value is lower than the second low-battery detection value (9.6 V), and that the power supply is changed (a switch to AC drive, a connection of the battery, or the like), changes the low-battery detection value to the second low-battery detection value (9.6 V).

In the case where the low-battery detection value is changed to the second low-battery detection value, the electronic apparatus (PC) 10 of the embodiment detects the low battery of the battery based on the changed second low-battery detection value.

The electronic apparatus (PC) 10 of the embodiment includes a mode detection section which detects whether or not the long-life mode of the battery 15 is set.

In the electronic apparatus (PC) 10 of the embodiment, the battery detection value is detected based on the voltage or the remaining amount of the battery.

The electronic apparatus (PC) 10 of the embodiment includes a deterioration detection section (the microcomputer 13) which detects a deterioration of the battery 15.

The electronic apparatus (PC) 10 of the embodiment includes a display section (the display section 18, FIG. 3) which displays the setting as to the long-life mode.

The electronic apparatus (PC) 10 of the embodiment includes a display section (the display section 18, FIG. 3) which displays the setting as to the low battery.

The electronic apparatus (PC) 10 of the embodiment includes a display section (the display section 18, FIG. 3) which displays the setting as to the deterioration of the battery.

In the electronic apparatus (PC) 10 of the embodiment, when “Low-battery detection level” is changed, the reduction rate of the battery capacity due to the cycle characteristic can be relieved, and the life of the battery can be prolonged.

The user can select the function of the embodiment. For example, the user can select/designate the function as Normal mode/Long-life mode or the like. In “Long-life mode”, plural modes may exist depending on the degree of change of “Low-battery detection level”.

In the embodiment, furthermore, it is possible also to determine the deterioration degree of the battery from the battery information. The electronic apparatus has also the function of, if it is determined that deterioration proceeds to some extent, changing “Low-battery detection level” to prolong “Battery life”.

As a result of the deterioration determination, the user may select whether the change of “Low-battery detection level” is operated or not. According to the configuration, in the embodiment, it is possible to prolong the life of the battery (secondary cell) which is used in the electronic apparatus.

The whole procedure of the control process in the embodiment can be executed by software. Therefore, effects similar to those of the embodiment can be easily achieved simply by installing and executing programs for executing the procedure of the control process in a usual computer through a computer-readable recording medium storing the programs.

The embodiment is not limited to the description as it is, and, in the stage of implementation, the invention can be embodied while the components are variously modified without departing the spirit of the invention. By appropriate combinations of plural components disclosed in the embodiment, various inventions can be configured. For example, some of the components may be omitted from all of the components shown in the embodiment. Moreover, the components in different embodiments may be appropriately combined.

1. An electronic apparatus including:
a comparison section which, in a case where a long-life mode of a battery is set, compares a battery detection value with a second low-battery detection value that is higher than a first low-battery detection value;
a change detection section which detects a change of a power supply; and
a change reflect section which, in a case where it is detected both that the battery detection value is lower than the second low-battery detection value, and that the power supply is changed, changes the low-battery detection value to the second low-battery detection value.

2. The electronic apparatus of claim 1,
wherein, in a case where the low-battery detection value is changed to the second low-battery detection value, the electronic apparatus detects a low battery of the battery based on the changed second low-battery detection value.

3. The electronic apparatus of claim 1,
wherein the electronic apparatus includes a mode detection section which detects whether or not the long-life mode of the battery is set.

4. The electronic apparatus of claim 1,
wherein the battery detection value is detected based on a voltage or a remaining amount of the battery.

5. The electronic apparatus of claim 1,
wherein the electronic apparatus includes a deterioration detection section which detects a deterioration of the battery.

6. The electronic apparatus of claim 1,
wherein the electronic apparatus includes a display section which displays setting as to the long-life mode.

7. The electronic apparatus of claim 1,
wherein the electronic apparatus includes a display section which displays setting as to a low battery.

8. The electronic apparatus of claim 5,
wherein the electronic apparatus includes a display section which displays setting as to a deterioration of the battery.

9. A method of controlling an electronic apparatus including:
comparing, in a case where a long-life mode of a battery is set, a battery detection value with a second low-battery detection value that is higher than a first low-battery detection value;
detecting a change of a power supply; and
changing, in a case where it is detected both that the battery detection value is lower than the second low-battery detection value, and that the power supply is changed, the low-battery detection value to the second low-battery detection value.

10. A storage medium which stores a program for controlling an electronic apparatus, the program including:
comparing, in a case where a long-life mode of a battery is set, a battery detection value with a second low-battery detection value that is higher than a first low-battery detection value;
detecting a change of a power supply; and
changing, in a case where it is detected both that the battery detection value is lower than the second low-battery detection value, and that the power supply is changed, the low-battery detection value to the second low-battery detection value.
